(19) United States
(12) Patent Application Publication
(10) Pub. No.: US 2006/0049494 A1
(43) Pub. Date: Mar. 9, 2006

(54) Semiconductor device

(75) Inventor: Tatsuhiro Urushido, Sakata-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/189,728

(22) Filed: Jul. 27, 2005

(30) Foreign Application Priority Data
Sep. 6, 2004 (JP) 2004-258194

(51) Int. Cl. H01L 23/495

(52) U.S. Cl. 257/666

(57) ABSTRACT

A semiconductor device comprises; a semiconductor chip including a first and second groups of pads; and a wiring substrate including a first and second groups of leads, wherein the first group pads are arranged in line with a first line extending along one side of the semiconductor chip; the second group pads are arranged in line with a second line located the further inside of the semiconductor chip more than the location of first line and extending along one side of the semiconductor chip; and each of a first and second groups of leads includes a joint part, a bending part extended to the joint part and an end part extended to the bending part; wherein the semiconductor chip is mounted on the substrate such that the first group pads oppose the joint parts of the first group leads and the second group pads oppose the joint parts of the second group leads; the joint parts of the first group leads extend along any of a plural of lines passing through a first point; the joint parts of the second group leads extend along any of a plural of lines passing through a second point; and the first and second group leads are extracted from the side of the semiconductor chip.

### BACKGROUND

1. Technical Field

The present invention relates a semiconductor device.

2. Related Art

It is well known a semiconductor device in which a semiconductor chip is mounted on a wiring substrate and a pad of the semiconductor chip is electrically coupled with a lead of the wiring substrate with pong each other. Pad's numbers have been recently increased, accompanied with minimizing pitches of them. But, it is important to surely oppose each of pads to a lead, as enhancing liability of a semiconductor device. Japanese Unexamined Patent Publication No. 2003-198374 is an example of related art.

### SUMMARY

The advantage of the present invention is to provide a semiconductor device having a highly reliable structure, which is manufactured with high efficiency.

According to an aspect of the invention, a semiconductor device comprises a semiconductor chip including first and second groups of pads and a wiring substrate including first and second groups of leads. The first group pads are arranged in line with a line extending along one side of the semiconductor drip. The second group pads are arranged in line with a second line located the further inside of the semiconductor chip more than the first line and extending along one side of the semiconductor chip. Each of first and second groups of leads includes a joint park and a bending part extended to the joint part and an end part extended to the bending part. The semiconductor chip is mounted on the substrate such that the first group pads oppose the joint part of the first group leads and the second group pads oppose the joint part of the second group of leads; the joint part of the first group leads extends along any of a plural of lines passing through a first point; the joint part of the second group leads extends along any of a plural of lines passing through a second point; the first and second group leads are extracted from the side of the semiconductor chip.

According to this aspect of the invention, each of the joint parts of the first group leads extends along with any of a plurality of lines passing through a first point and each of the joint parts of the second group leads extends along with any of a plurality of lines passing through a second point. Hence, the joint part of the lead opposes the pad of the semiconductor thereby, even if the wiring substrate expands or shrinks. The first and second group leads are extracted from the side of the semiconductor chip. This extracting prevents leads from contacting each other even if a plurality of joint parts are arranged in a plurality of lines. Therefore, the structure provides a semiconductor device having a highly reliable shire, which is manufactured with high efficiency.

In the semiconductor device of the invention, the first and second points may be located shifting toward the direction perpendicular to the first and second lines and the distance between the first point and the first line may be equivalent to the distance between the second point and the second line. In the semiconductor device, the fist point may be overlapped with the second point

In the semiconductor device of the invention, the end parts of the second group leads may be located so as to go through the first group pads.

In the semiconductor device of the invention, the end parts of the second group leads may extend toward the direction across the first and second lines within a region, which overlaps the semiconductor chip.

In the semiconductor device of the invention, the end parts of the first and second group leads may extend in parallel each other within a region, which overlaps the semiconductor chip.

### BRIEF DESCRIPTION OF THE DRAWINGS

The invention will be descried with reference to the accompanying drawings, wherein like numbers refer to like elements, and wherein

FIG. 1 shows a semiconductor device of a embodiment of the invention;

FIG. 2 shows a semiconductor device of the embodiment of the invention;

FIG. 3 shows a semiconductor device of the embodiment of the invention,

FIG. 4 shows a semiconductor device of the embodiment of the invention;

FIG. 5 shows a semiconductor device of the embodiment of the invention;

FIG. 6 shows an electronic device in which the semiconductor device of the embodiment of the invention is mounted;

FIG. 7 shows an electronic device in which the semiconductor device of the embodiment of the invention is mounted;

FIG. 8 shows an electronic device in which the semiconductor device of the embodiment of the invention is mounted and

FIG. 9 shows a semiconductor device of a modification of the embodiment of the invention.

### DESCRIPTION OF THE EMBODIMENTS

Embodiments of the invention will now be described with reference to the accompanying drawings. But the essence of the present invention is not limited to the following embodiment.

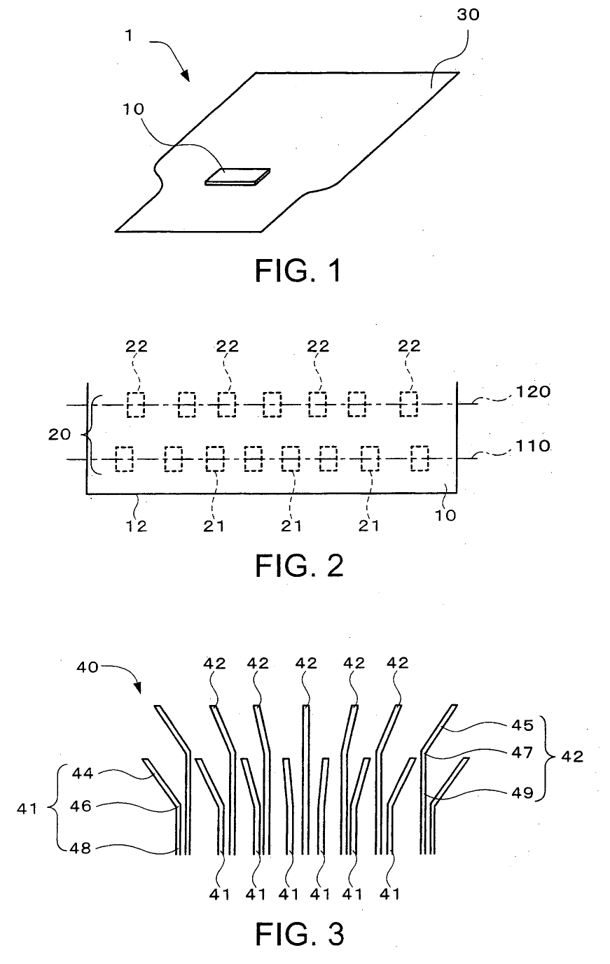

FIG. 1 to FIG. 5 show a semiconductor device of an embodiment of the invention. FIG. 1 is a schematic view of a semiconductor device 1 of the embodiment of the invention.

The semiconductor device 1 of the embodiment includes a semiconductor chip 10 as shown in FIG. 1. An integrated circuit 11 may be installed in the semiconductor chip 10 as shown in FIG. 5. A structure of the integrated circuit 11 is not specifically limited, but may include active elements such as transistors and passive elements such as resisters, capacitors and coils. The semiconductor chip 10 includes pads 20 as shown in FIG. 2. FIG. 2 shows an arrangement of pads 20 of the semiconductor chip 10. Pads 20 may be electrically connected to the integrated circuit 11. Otherwise, the pads 20 may further include pads, which are not electrically connected to the integrated circuit 11. Pads 20 include first and second groups pads 21 and 22. The first group pads are arranged in line with a line extending along one side 12 of the semiconductor chip 10. Here, the first line 110 may be a line extending parallel with the side 12. The second group pads are arranged in line with a line extending along a second line 120 extending the first line. The second line 120 is located further inside of the semiconductor chip 10 comparing to the first line 110. As shown in FIG. 2, pads 20 may be arranged in a zigzag state. Otherwise, the first and second group pads may be arranged shifting toward the direction perpendicular to the first and second lines 110 and 120.

The semiconductor device 1 of the embodiment includes a wiring substrate 30 as shown in FIG. 1. A material of the wing substrate 30 is not specifically limited, but may be organic (epoxy substrate, for example), inorganic (a ceramic or a glass substrate) or complex of them (a glass epoxy substrate, for example). The wiring substrate 30 may be a rigid substrate. Otherwise, the substrate 30 may be a flexible substrate such as a polyester substrate and a ployimide substrate. The wiring substrate 30 may be a substrate for a chip on film (COF). The wiring substrate may be a single layer substrate or a multiple layers substrate. The configuration and thickness of the wiring substrate 30 is not specifically limited.

The wiring substrate 30 includes a lead 40 as shown in FIG. 3. The lead 40 may be a multi or single layered film made of copper, chrome, titan, nickel, titan-tungsten gold, aluminum, nickel vanadium and tungsten. Further, when a glass substrate is used as the wiring substrate 30, the lead 40 may be made of a metal film such as indium-oxide (ITO), chrome and aluminum, a metal compound film and a film in which these are complex. Manufacturing the lead 40 is not specifically limited. The lead 40 may be formed by sputtering or an active method such as electroless plating. The lead 40 may be plated with solder, tin, gold and nickel. As shown in FIG. 3, the lead 40 includes a first and second group leads 41 and 42. The first group leads 41 include a joint part 44, a bending part 46 extending to the joint part 44 and an end part 48 extending to the bending part 46. Further, the send group leads 42 include a joint part 45, a bending part 47 extending to the joint part 45 and an end part 49 extending to the bending part 47. Namely, as shown in FIG. 3, the first and second group leads 41 and 42 include joint parts 44 and 45, bending parts 46 and 47 extending to joint parts 44 and 45 and end parts 48 and 49 extending to bending parts 46 and 47.

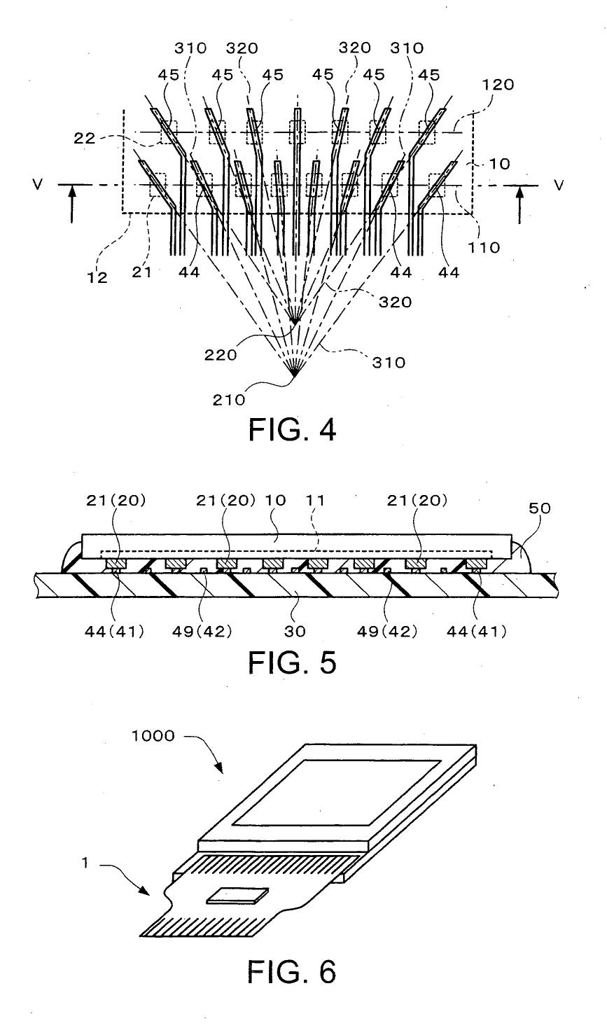

In a semiconductor device of the embodiment, the semiconductor chip 1 is mounted on the electrical wiring substrate 30, as shown in FIG. 1. Here, the first group and second group leads 41 and 42 are extracted from the side of the semiconductor chip 10, as shown in FIG. 4. Further, the fist group pads 21 oppose the joint parts 44 of the first group leads 41. Here, the pads 21 may be electrically connected to the joint parts 44. Further, the second group pads 22 oppose the joint parts 45 of the second group leads 42. Here, the pads 22 may be electrically connected to the joint parts 45. FIG. 5 is an enlarged view of cross section of the line V to V in FIG. 4. In FIG. 5, pads 21, 22 are electrically connected to joint parts 44, 45 by contacting each other. Otherwise, a conductive material may be incorporated into a space between the pads 20 and joint parts 44, 45 contacting them electrically each other (not shown.)

In a semiconductor device of the embodiment, the joint part 44 of the first group leads 41 extends along any of plural lines 310 passing through the first point 210 as shown in FIG. 4. The joint part 45 of the second group leads 42 extends along any of plural lines 320 crossing the second point 220. Therefore, when the wiring substrate 30 expands or shrinks with the same rate between lateral and longitudinal directions, the joint part 44 of the first group leads 41 moves along the line 310. The joint part 45 of the second group leads 42 moves along the line 320. Namely, when the wiring substrate 30 expands or shrinks with the same rate between lateral and longitudinal directions, the joint parts 44 and 45 move along the lines 310 and 320. The joint parts 44 oppose the pads 21 aligning the pads on the line 310. The joint parts 45 oppose the pads 22 aligning the pads 22 on the line 320. Namely, the pads 21 and 22 are designed to be arranged on the lines 310 and 320. The joint part 44 and 45 move along the lines 310 and 320 and the pads 21 and 22 are arranged on the lines 310 and 320 by expansion or shrink of the wiring substrate 30. Therefore, it is possible to make the pads 21 and 22 oppose joint parts 44 and 45, even in expansion or shrink of the wring substrate 30 before mounting the semiconductor chip 1. In other word, arranging mounting position of the semiconductor ship 10 releases affect of expansion or shrink of the wiring substrate 30. Hence, it is possible to manufacture a semiconductor device having electrically reliable connectivity, even in expansion or shirk of the wiring substrate 30. Therefore the structure of the embodiment provides a semiconductor device having a highly reliable structure, which is manufactured with high efficiency. Here, the fist and second points 210 and 220 may be arranged shifting toward a direction perpendicular to the first and second lines 110 and 120. The distance between the first point 210 and the first line 110 may be equivalent to the distance between the second point 220 and the second line 120. When the wiring substrate 30 expands or shrinks, the joint part 44 of the lead 41 and the joint part 45 of the lead 42 expand or shrink at the same rate. Hence, it is possible to provide a semiconductor device having a structure further releasing it from affect of expansion or shrink of the wiring substrate 30.

In a semiconductor device of the embodiment, the first and second leads 41 and 42 include bending parts 46 and 47 extended from joint parts 44 and 45, as mentioned before. Further, the first and second group leads 41 and 42 include end parts 48 and 49 extending from bending parts 46 and 47. Hence, this structure prevents the first group leads 41 from contacting with the second group leads 42 even when a plurality of pads are formed. Here, the second group leads 42 may be arranged passing through a space between pads 21 of the first group. The end part 49 of the second group leads 42 may be aged passing through a space between pads 21 of the first group as shown in FIG. 4. In other word the bending part 47 may be located further inside of the semiconductor chip 10 than the location of the first group pads 21. The end part 49 of the second group leads 42 extends toward the direction perpendicular to the fist and second lines 110 and 120 within a region overlapping the semiconductor chip 10, as shown in FIG. 4. These structures prevent the first group leads 41 from contacting with the second group leads 42 and the second group lead 42 from contacting with the fist group pads 21.

The semiconductor device of the embodiment may include a resin part 50 as shown in FIG. 5. The resin part 50 is located between the semiconductor chip 10 and the wiring substrate 30. The resin part 50 fixes the semiconductor chip 10 with the wiring substrate 30, making them not easy removed together and providing a reliable semiconductor device. Here, end parts 48 and 49 of the first and second groups leads 41 and 42 may extend in parallel each other within a region overlapping the semiconductor chip 10 as shown in FIG. 4. This structure enhances flowability of resin material between the semiconductor chip 10 and the wiring substrate 30 effectively filing the resin between the semiconductor chip 10 and the wing substrate 30. Namely, it can provide a semiconductor device having a highly reliable structure, which is effectively manufactured.

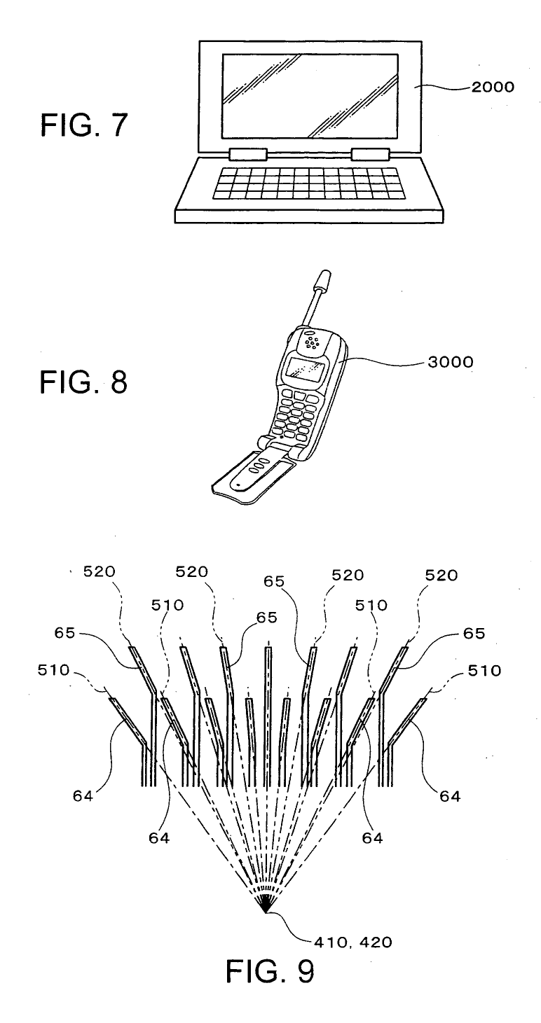

In the embodiment, a semiconductor device having pads arrange in two layers were explained, but it can be applied to a semiconductor device having pads a in more than three layers as a modification. FIG. 6 shows an electronic module 1000 having the semiconductor device 1. The electronic module 1000 may be an display. A display may be a liquid crystal display or elect luminescent display. Further, FIG. 7 shows a personal computer 2000 and FIG. 8 shows a mobile phone 3000 as an electronic apparatus having the semiconductor device 1.

(Modification)

FIG. 9 shows a modification of a first embodiment of the invention. In the modification, almost structures, which were already explained, are applied

In a semiconductor device of the modification, a joint part 64 of the first group leads extends along any of plural lines 510 passing a first point 410. The joint part 65 of the second group leads extends along any of plural lines 520 passing a second point 420. As shown in FIG. 9, the first point 410 overlaps the second point 420. In other word, the joint parts 64 and 65 may extend along any lines passing one point. This structure can release the effect of expansion or shrink of a wiring substrate. The structure provides a semiconductor device having a highly reliable stature, which is manufactured with high efficiency.

It should be noted that the present invention is not limited to the above-mentioned embodiments, and various ages and modifications can be made with the spirit and scope of the invention. For example, the present invention includes substantially the same structure (including the structure with the same functions, methods, and results and the structure with the same goals and results) as the structure of the above-mentioned embodiments. The present invention also includes other strut in which non-essential elements of the above-mentioned embodiments are substituted. The present invention also includes the sty that can achieve the same effects or the same goals as those achieved by the above-mentioned embodiments. Moreover, the present invention includes other in which known methods and techniques are incorporated into the above-mentioned embodiments.

What is claimed is:

1. A semiconductor device comprising;
a semiconductor chip including a first and second groups of pads; and
a wiring substrate including a fast and second groups of leads, wherein the first group pads are arranged in a first line extending along one side of the semiconductor chip; the second group pads are arranged in a second line located a further inside of the semiconductor chip more than a location of the first line and extending along one side of the semiconductor chip; and each of the first and second groups of leads includes a joint part, a bending part extended to the joint part and an end part extended to the bending part wherein the semiconductor chip is mounted on the substrate such that the first group pads oppose the joint parts of the fist group leads and the second group pads oppose the joint parts of the second group leads; the joint parts of the first group leads extend along any of a plural of lines passing through a fist point; the joint parts of the second group leads extend along any of a plural of lines passing through a second point; and the first and second group leads are extracted from the side of the semiconductor chip.

2. A semiconductor device according to claim 1, wherein the first and second points are located shifting toward the direction perpendicular to the first and second lines and the distance between the first point and the first line is equivalent to the distance between the second point and the second line.

3. A semiconductor device according to claim 1, wherein the fist point overlaps the second point.

4. A semiconductor device according to claim 1, wherein the end parts of the second group leads are located so as to go through the fist group pads.

5. A semiconductor device according to claim 1, wherein the end parts of the second group leads extend toward the direction across the first and second lines within a region, which overlaps the semiconductor chip.

6. A semiconductor device according to claim 1, wherein the end parts of the first and second group leads extend in parallel each other within a region which overlaps the semiconductor chip.
